(19) United States
(12) Patent Application Publication
(10) Pub. No.: US 2026/0282226 A1
(43) Pub. Date: Sep. 17, 2026

(54) MULTI-LAYER BOARD

(71) Applicant: TONG HSING ELECTRONIC INDUSTRIES, LTD., Taoyuan City (TW)

(72) Inventors: YI-YUAN LIN, Taoyuan City (TW); SHIH-HAN WU, Taipei City (TW); JIAN-YU SHIH, Taoyuan City (TW)

(21) Appl. No.: 19/681,112

(22) Filed: May 19, 2026

Related U.S. Application Data
(63) Continuation of application No. 19/672,750, filed on May 11, 2026.
Application No. 19/672,750 is a continuation-in-part of application No. 19/372,212, filed on Oct. 28, 2025.
(60) Provisional application No. 63/748,821, filed on Jan. 23, 2025.

(30) Foreign Application Priority Data
Jul. 9, 2025 (TW) 114125893
Oct. 7, 2025 (TW) 114138493
Mar. 24, 2026 (TW) 115111090

(51) Int. Cl. H05K 1/11; H05K 1/02; H05K 1/03; H05K 1/09; H05K 1/181; H05K 1/185

(52) U.S. Cl. CPC H05K 1/113; H05K 1/0201; H05K 1/0306; H05K 1/092; H05K 1/181; H05K 1/185; H05K 2201/09381; H05K 2201/09481; H05K 2201/09527; H05K 2201/09536; H05K 2201/096; H05K 2201/09618; H05K 2201/09827; H05K 2201/10522

(57) ABSTRACT

A multi-layer board includes two core layers and a connection layer connected between the two core layers. Each of the two core layers includes a substrate and a conductor embedded in the substrate. One of the two substrates is a ceramic substrate, and another one of the two substrates is one of a ceramic substrate, a glass substrate, and a copper foil substrate. Each of the conductors has an internal connection surface that is coplanar with a surface of the corresponding substrate. The connection layer includes an insulating layer sandwiched between the two substrates and a conductive paste embedded in the insulating layer. The conductive paste connects and is sintered to the internal connection surfaces of the two core layers.

### CROSS-REFERENCE TO RELATED PATENT APPLICATION

This application claims the benefit of priority to Taiwan Patent Application No. 114125893, filed on July 9, 2025, No. 114138493, filed on October 7, 2025, and No. 115111090, filed on March 24, 2026. The entire contents of the above identified applications are incorporated herein by reference.

This application claims the benefit of priority to the U.S. Provisional Patent Application Ser. No. 63/748,821, filed on January 23, 2025, which application is incorporated herein by reference in its entirety.

This application is a continuation application of the U.S. Patent Application Ser. No. 19/672,750, filed on May 11, 2026, and entitled “HYBRID CIRCUIT BOARD,” now pending, the entire disclosures of which are incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit board, and more particularly to a hybrid circuit board.

### BACKGROUND OF THE DISCLOSURE

A conventional hybrid circuit board uses a silicon substrate or a single glass substrate as a core layer, such that a heat dissipation property and an anti-bending property of the conventional hybrid circuit board are limited by the silicon substrate and the single glass substrate, and are difficult to be improved.

### SUMMARY OF THE DISCLOSURE

In response to the above-referenced technical inadequacies, the present disclosure provides a hybrid circuit board for effectively improving on the issues associated with conventional hybrid circuit boards.

In order to solve the above-mentioned problems, one of the technical aspects adopted by the present disclosure is to provide a hybrid circuit board, which includes a multi-layer board, a first stacked layer, and a second stacked layer. The first stacked layer and the second stacked layer are respectively formed on two opposite sides of the multi-layer board and are electrically coupled to each other through the multi-layer board. Each of the first stacked layer and the second stacked layer is configured to allow at least one electronic component to be connected thereon. The multi-layer board includes a first core layer, a second core layer stacked on the first core layer along a thickness direction, and a connection layer that is connected between the first core layer and the second core layer. The first core layer includes a first substrate and a first conductor. The first substrate has a first thru-hole, and the first substrate is a ceramic substrate. The first conductor is filled in the first thru-hole, and the first conductor has a first internal connection surface that is coplanar with a surface of the first substrate. The second core layer includes a second substrate and a second conductor. The second substrate has a second thru-hole, and the second substrate is one of a ceramic substrate, a glass substrate, and a copper foil substrate. The second conductor is filled in the second thru-hole. The second conductor has a second internal connection surface that is coplanar with a surface of the second substrate. The first internal connection surface of the first core layer faces the second internal connection surface of the second core layer along the thickness direction. The connection layer includes an insulating layer and a conductive paste that is embedded in the insulating layer. The insulating layer is sandwiched between the first substrate and the second substrate. The conductive paste connects and is sintered to the first internal connection surface of the first conductor and the second internal connection surface of the second conductor.

Therefore, the hybrid circuit board of the present disclosure replaces conventional silicon substrate or conventional glass substrate with a multi-layer board, and ensures that the first stacked layer and the second stacked layer are electrically coupled to each other through the multi-layer board, thereby effectively improving the heat dissipation and bending resistance of the hybrid circuit board.

Furthermore, in the multi-layer board provided by the present disclosure, the first substrate in the multi-layer board uses a ceramic substrate as the skeleton for the multi-layer board, so that the second substrate can selectively use a ceramic substrate with higher strength, a glass substrate with better high-frequency signal transmission performance, or a copper foil substrate with lower cost, thereby meeting various market requirements.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a hybrid circuit board according to a first embodiment of the present disclosure;

FIG. 2 is a schematic enlarged view of region II of FIG. 1;

FIG. 3 is a schematic view showing the multi-layer board provided for another usage state according to the first embodiment of the present disclosure;

FIG. 4 is a schematic cross-sectional view of the hybrid circuit board according to a second embodiment of the present disclosure;

FIG. 5 is a schematic cross-sectional view of the hybrid circuit board according to a third embodiment of the present disclosure;

FIG. 6 is a schematic enlarged view of region VI of FIG. 5;

FIG. 7 is a schematic cross-sectional view showing the hybrid circuit board having another configuration according to the third embodiment of the present disclosure;

FIG. 8 is a schematic cross-sectional view of the hybrid circuit board according to a fourth embodiment of the present disclosure;

FIG. 9 is a schematic cross-sectional view showing the hybrid circuit board having another configuration according to the fourth embodiment of the present disclosure;

FIG. 10 is a schematic top view showing a part of FIG. 8 when the first dielectric layer is omitted; and

FIG. 11 is a schematic cross-sectional view showing the hybrid circuit board having yet another configuration according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### [First Embodiment]

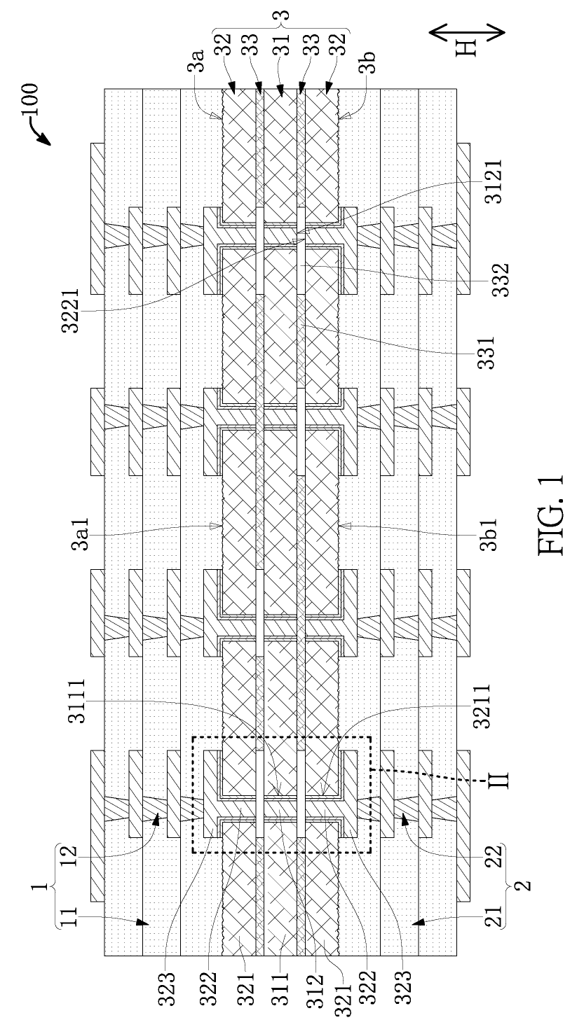

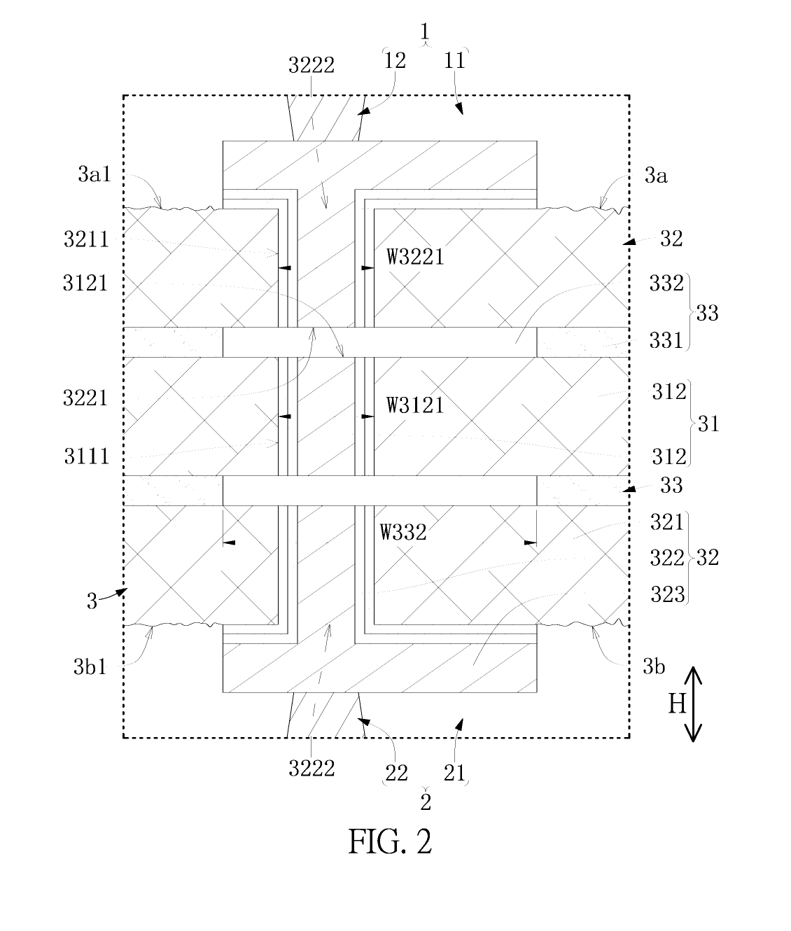

Referring to FIG. 1 to FIG. 3, a first embodiment of the present disclosure is provided. As shown in FIG. 1 and FIG. 2, the present embodiment provides a hybrid circuit board 100, which includes a multi-layer board 3, a first stacked layer 1, and a second stacked layer 2, the latter two of which are respectively formed on two opposite sides of the multi-layer board 3. The multi-layer board 3 is formed by stacking multiple core layers, and the first stacked layer 1 and the second stacked layer 2 can be electrically coupled to each other through the multi-layer board 3. The first stacked layer 1 and the second stacked layer 2 are each configured to allow at least one electronic component (not shown in the drawings, for example, a circuit board or a power chip) to be connected thereon. In other words, any circuit board that does not employ multiple core layers is different from the hybrid circuit board 100 provided by the present embodiment.

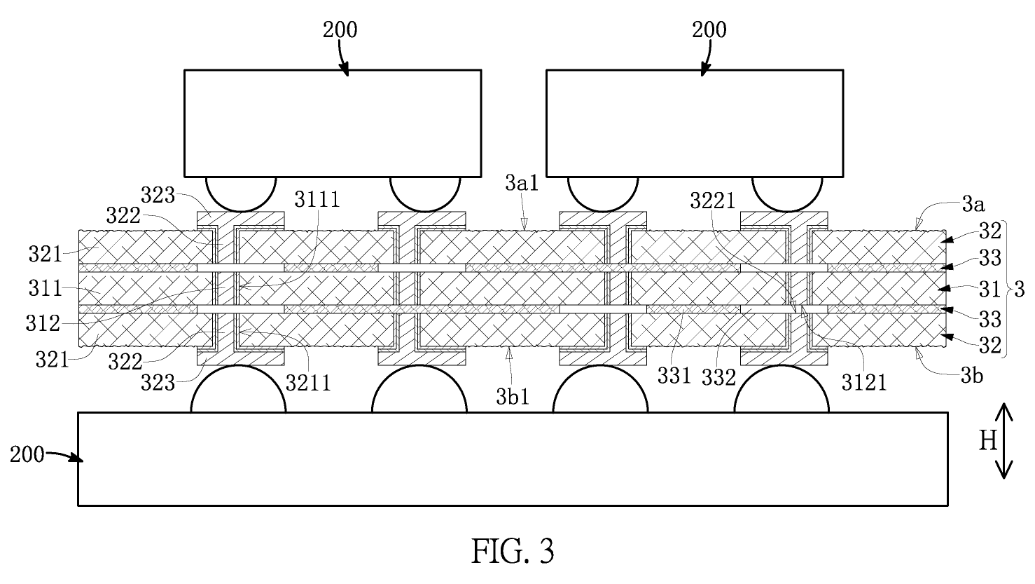

It should be noted that, although the multi-layer board 3 shown in FIG. 1 and FIG. 2 of the present embodiment is in cooperation with the first stacked layer 1 and the second stacked layer 2, the present disclosure is not limited thereto. For example, as shown in FIG. 3, the multi-layer board 3 can be applied independently according to practical requirements, and can be used to allow at least one electronic component 200 to be connected thereon.

In the present embodiment, as shown in FIG. 1 and FIG. 2, the multi-layer board 3 includes a first core layer 31, two second core layers 32 stacked on two opposite sides of the first core layer 31 along a thickness direction H, and two connection layers 33 that are located between the first core layer 31 and the two second core layers 32, but the present disclosure is not limited thereto. For example, in other embodiments of the present disclosure not shown in the drawings, a quantity of the second core layers 32 of the multi-layer board 3 can be one or at least three according to practical requirements.

The first core layer 31 includes a first substrate 311 and a plurality of first conductors 312 that are embedded in the first substrate 311. In the present embodiment, the first substrate 311 is a ceramic substrate and has a plurality of first thru-holes 3111, and the first conductors 312 are respectively filled in the first thru-holes 3111, but the present disclosure is not limited thereto.

It should first be noted that, a quantity of the first thru-holes 3111 of the first substrate 311 and a quantity of the first conductors 312 as shown in the drawings of the present embodiment are each more than one, but in other embodiments of the present disclosure not shown in the drawings, the quantity of the first thru-holes 3111 and the quantity of the first conductors 312 can each be at least one. In addition, for ease of understanding the present embodiment, the following description describes the structure and connection relationship of one of the first conductors 312 and a corresponding one of the first thru-holes 3111.

Specifically, the first conductor 312 has two first internal connection surfaces 3121 respectively arranged at two ends thereof, and each of the two first internal connection surfaces 3121 of the first conductor 312 is coplanar with an adjacent surface of the first substrate 311. In order to allow the first conductor 312 to be stably formed and bonded to the first substrate 311, the first conductor 312 can be of a multi-layer structure that includes a seed layer formed on the first substrate 311 and a conductive layer formed on the seed layer. In the present embodiment, the seed layer includes a copper alloy layer (e.g., a titanium-copper layer or a nickel-copper layer) formed on the first substrate 311 in a deposition manner and a copper layer that is formed on the copper alloy layer in an electroless plating manner, and the conductive layer is formed on the copper layer in a direct copper plating (DPC) manner, but the present disclosure is not limited thereto.

In addition, as the two second core layers 32 in the present embodiment are of substantially the same structure, the following description discloses the structure and connection relationship among just one of the second core layers 32, the first core layer 31, and a corresponding one of the connection layers 33, but the present disclosure is not limited thereto. For example, in other embodiments of the present disclosure not shown in the drawings, the second core layers 32 included in the multi-layer board 3 can be of different structures according to practical requirements.

The second core layer 32 includes a second substrate 321, a plurality of second conductors 322 embedded in the second substrate 321, and a plurality of external connection conductors 323 that are respectively connected to the second conductors 322. The second substrate 321 is one of a ceramic substrate, a glass substrate, and a copper clad laminate (CCL) substrate, and the second substrate 321 has an inner surface adjacent to the first substrate 311 and an outer surface that is away from the first substrate 311.

In the present embodiment, the second substrate 321 has a plurality of second thru-holes 3211, the second conductors 322 are respectively filled in the second thru-holes 3211, and each of the external connection conductors 323 is integrally connected to a corresponding one of the second conductors 322 and is formed on the outer surface (e.g., the external connection conductor 323 being formed on the outer surface of the second substrate 321 in a direct copper plating manner), but the present disclosure is not limited thereto.

It should be noted that, a quantity of the second thru-holes 3211 of the second substrate 321, a quantity of the second conductors 322, and a quantity of the external connection conductors 323 as shown in the drawings of the present embodiment are each more than one, but in other embodiments of the present disclosure not shown in the drawings, the quantity of the second thru-holes 3211, the quantity of the second conductors 322, and the quantity of the external connection conductors 323 can each be at least one. In addition, for ease of understanding the present embodiment, the following description describes the structure and connection relationship of one of the second conductors 322, a corresponding one of the second thru-holes 3211, and a corresponding one of the external connection conductors 323.

Specifically, the second conductor 322 has a second internal connection surface 3221 and an external connection surface 3222. The second internal connection surface 3221 and the external connection surface 3222 are respectively arranged on two opposite side of the second conductor 322, the second internal connection surface 3221 of the second conductor 322 is coplanar with the inner surface of the second substrate 321, and the external connection surface 3222 of the second conductor 322 is coplanar with the outer surface of the second substrate 321 and is connected to the external connection conductor 323. In other words, the external connection conductor 323 is arranged away from the second internal connection surface 3221. In order to allow the second conductor 322 and the external connection conductor 323 to be stably formed and bonded to the second substrate 321, each of the second conductor 322 and the external connection conductor 323 can be of a multi-layer structure that includes a seed layer formed on the second substrate 321 and a conductive layer formed on the seed layer. In the present embodiment, the seed layer includes a copper alloy layer (e.g., a titanium-copper layer or a nickel-copper layer) formed on the second substrate 321 in a deposition manner and a copper layer that is formed on the copper alloy layer in an electroless plating manner, and the conductive layer is formed on the copper layer in a direct copper plating manner, but the present disclosure is not limited thereto.

The connection layer 33 is connected between the first core layer 31 and the second core layer 32, and the connection layer 33 includes an insulating layer 331 and a conductive paste 332 that is embedded in the insulating layer 331. The insulating layer 331 is sandwiched between the first substrate 311 and the second substrate 321, and the insulating layer 331 can be an organic material, such as ajinomoto build-up film (ABF), polypropylene (PP), polyimide (PI), epoxy resin, or liquid crystal polymer (LCP).

Furthermore, the conductive paste 332 connects and is sintered to the first internal connection surface 3121 of the first conductor 312 and the second internal connection surface 3221 of the second conductor 322, and a width W332 of the conductive paste 332 is greater than a width W3121 of the first internal connection surface 3121 and is greater than a width W3221 of the second internal connection surface 3221. In the present embodiment, the conductive paste 332 can include a solder paste, an active metal brazing (AMB) paste, a nano silver paste, a nano copper paste, or a nanoscale colloidal gold, but the present disclosure is not limited thereto.

Specifically, the first internal connection surface 3121 of the first core layer 31 faces the second internal connection surface 3221 along the thickness direction H. In the present embodiment, a wall of the first substrate 311 defining the first thru-hole 3111 is flush with a wall of the second substrate 321 defining the second thru-hole 3211 along the thickness direction H. In other words, a projection region defined by orthogonally projecting the first internal connection surface 3121 onto the second core layer 32 along the thickness direction H completely overlaps the second internal connection surface 3221 and does not overlap with the second substrate 321, but the present disclosure is not limited thereto.

It should be noted that the multi-layer board 3 has a first surface 3a and a second surface 3b that is opposite to the first surface 3a, and the first surface 3a and the second surface 3b of the multi-layer board 3 in the present embodiment are the outer surfaces of the two second substrates 321, respectively.

Furthermore, in order to improve the bonding strength of the multi-layer board 3 relative to the first stacked layer 1 and the second stacked layer 2, the multi-layer board 3 can have a first modification region 3a1 arranged on the first surface 3a and connected to the first stacked layer 1, and a second modification region 3b1 that is arranged on the second surface 3b and that is connected to the second stacked layer 2. An area of the first modification region 3a1 and an area of the second modification region 3b1 can be adjusted according to practical requirements, but the present disclosure is not limited thereto.

In addition, the modification methods for the first modification region 3a1 and the second modification region 3b1 can adopt physical modification (e.g., roughening or surface coating) or chemical modification (e.g., changing the molecular structure of materials or surface functional groups) according to practical requirements. For example, the first surface 3a and/or the second surface 3b can be modified by laser or wet processes to form the first modification region 3a1 and the second modification region 3b1, thereby improving adhesion of the multi-layer board 3 relative to the first stacked layer 1 and the second stacked layer 2.

The first stacked layer 1 includes a first dielectric layer 11 formed on the first surface 3a and a first circuit 12 that is embedded in the first dielectric layer 11. In the present embodiment, the first dielectric layer 11 can be a multi-layer structure, and the first dielectric layer 11 can adopt an inorganic dielectric layer or an organic dielectric layer according to practical requirements, but the present disclosure is not limited thereto.

Specifically, at least one of the external connection conductors 323 is embedded in the first dielectric layer 11, and the first dielectric layer 11 is connected to (or covers) the first modification region 3a1 to improve the bonding strength between the first dielectric layer 11 and the multi-layer board 3.

Furthermore, one end of the first circuit 12 is connected to the multi-layer board 3 (e.g., one of the external connection conductors 323), and another end of the first circuit 12 is exposed from the first dielectric layer 11. It should be noted that, the first circuit 12 as shown in the drawings of the present embodiment is located approximately above the corresponding first thru-hole 3111, but in other embodiments of the present disclosure not shown in the drawings, the first circuit 12 can be staggered relative to the corresponding first thru-hole 3111 according to practical requirements.

The second stacked layer 2 includes a second dielectric layer 21 formed on the second surface 3b and a second circuit 22 that is embedded in the second dielectric layer 21. In the present embodiment, the second dielectric layer 21 can be a multi-layer structure, and the second dielectric layer 21 can adopt an inorganic dielectric layer or an organic dielectric layer according to practical requirements, but the present disclosure is not limited thereto.

It should be noted that, when the first dielectric layer 11 and/or the second dielectric layer 21 adopts the organic dielectric layer, the material of the organic dielectric layer can be selected from at least one of polyimide (PI), ajinomoto Build-up Film (ABF), liquid crystal polymer (LCP), acrylic, thermoplastics, thermosetting materials, polybenzoxazole (PBO), benzocyclobutene (BCB), epoxy resin, cyanate ester resin, polytetrafluoroethylene, polyester, polyolefin, SU-8, and hybrid polymer-ceramic materials.

Furthermore, when the first dielectric layer 11 and/or the second dielectric layer 21 adopts the inorganic dielectric layer, the material of the inorganic dielectric layer can be selected from at least one of silicon dioxide (SiO₂), aluminum oxynitride (AlON), zirconia-toughened alumina (ZTA), beryllium oxide (BeO), silicon carbide (SiC), aluminum oxide (Al₂O₃), aluminum nitride (AlN), silicon nitride (Si₃N₄), zirconium dioxide (ZrO₂), quartz, mica, hafnium oxide (HfO₂), tantalum pentoxide (Ta₂O₅), magnesium oxide (MgO), titanium dioxide (TiO₂), and boron nitride (BN).

Specifically, at least one of the external connection conductors 323 is embedded in the second dielectric layer 21, and the second dielectric layer 21 is connected to (or covers) the second modification region 3b1 to improve the bonding strength between the second dielectric layer 21 and the multi-layer board 3.

Furthermore, one end of the second circuit 22 is connected to the multi-layer board 3 (e.g., one of the external connection conductors 323), and another end of the second circuit 22 is exposed from the second dielectric layer 21. It should be noted that, the second circuit 22 as shown in the drawings of the present embodiment is located approximately below the corresponding second thru-hole 3211, but in other embodiments of the present disclosure not shown in the drawings, the second circuit 22 can be arranged in an offset configuration relative to the corresponding second thru-hole 3211 according to practical requirements.

Based on the above, the hybrid circuit board 100 provided in the present embodiment replaces conventional silicon substrate or conventional glass substrate with the multi-layer board 3, and ensures that the first stacked layer 1 (e.g., the first circuit 12) and the second stacked layer 2 (e.g., the second circuit 22) are electrically coupled to each other through the multi-layer board 3, thereby effectively improving the heat dissipation and bending resistance of the hybrid circuit board 100.

Furthermore, in the hybrid circuit board 100 provided by the present embodiment, the first substrate 311 in the multi-layer board 3 uses a ceramic substrate as the skeleton for the multi-layer board 3, so that the second substrate 321 can selectively use a ceramic substrate with higher strength, a glass substrate with better high-frequency signal transmission performance, or a copper foil substrate with lower cost, thereby meeting various market requirements.

### [Second Embodiment]

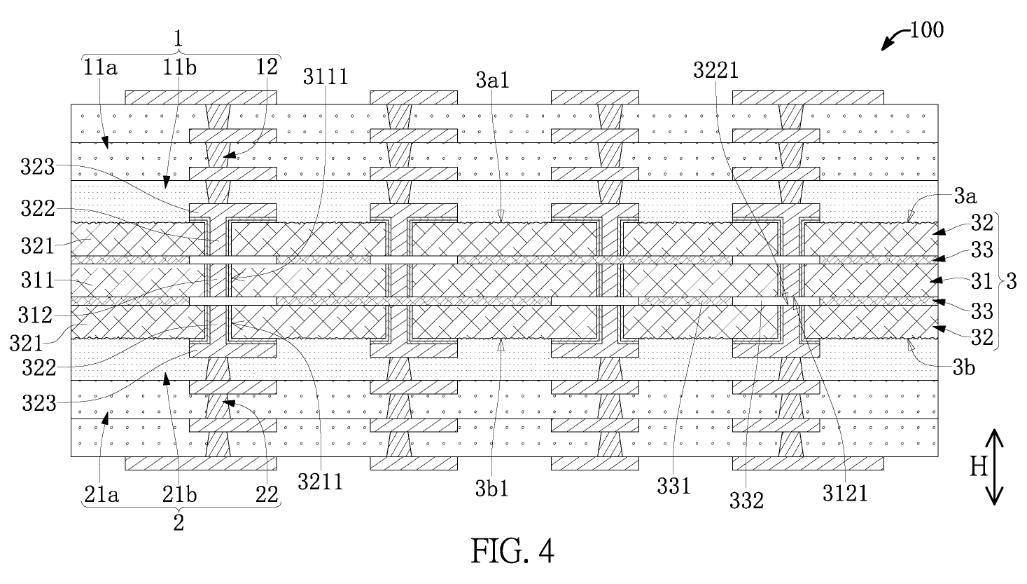

Referring to FIG. 4, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

The present embodiment discloses a hybrid circuit board 100, which includes a multi-layer board 3, and a first stacked layer 1, and a second stacked layer 2, the latter two of which are respectively formed on two opposite sides of the multi-layer board 3. The first stacked layer 1 and the second stacked layer 2 can be electrically coupled to each other through the multi-layer board 3. In other words, any circuit board that does not employ a multi-layer board is different from the hybrid circuit board 100 provided by the present embodiment. It should be noted that the structure of the multi-layer board 3 in the present embodiment is substantially the same as that described in the first embodiment, and will not be described herein for the sake of brevity.

The first stacked layer 1 is formed on the first surface 3a of the multi-layer board 3, and at least one of the external connection conductors 323 is embedded in the first stacked layer 1. The first stacked layer 1 includes a first organic dielectric layer 11a, and a first inorganic dielectric layer 11b, and a first circuit 12 that is embedded in the first organic dielectric layer 11a and the first inorganic dielectric layer 11b. The first organic dielectric layer 11a and the first inorganic dielectric layer 11b are stacked on the first surface 3a.

Specifically, the first organic dielectric layer 11a can be a single-layer structure or a multi-layer structure, and the first inorganic dielectric layer 11b can be a single-layer structure or a multi-layer structure. Furthermore, one end of the first circuit 12 is connected to the multi-layer board 3 (e.g., one of the external connection conductors 323), and another end of the first circuit 12 is exposed from one of the first organic dielectric layer 11a and the first inorganic dielectric layer 11b. It should be noted that the structure of the first circuit 12 in the present embodiment is substantially the same as that described in the first embodiment, and will not be described herein for the sake of brevity.

In the drawings of the present embodiment, the first stacked layer 1 is configured with the first inorganic dielectric layer 11b formed on the first surface 3a and connected to the first modification region 3a1, so that at least one of the external connection conductors 323 is embedded in the first inorganic dielectric layer 11b. Moreover, the first organic dielectric layer 11a is stacked on the first inorganic dielectric layer 11b, so that the another end of the first circuit 12 is exposed from the first organic dielectric layer 11a, but the present disclosure is not limited thereto.

For example, in other embodiments of the present disclosure not shown in the drawings, the first stacked layer 1 can be configured with the first organic dielectric layer 11a formed on the first surface 3a and connected to the first modification region 3a1, so that at least one of the external connection conductors 323 is embedded in the first organic dielectric layer 11a, and the first inorganic dielectric layer 11b is stacked on the first organic dielectric layer 11a for enabling the another end of the first circuit 12 to be exposed from the first inorganic dielectric layer 11b.

The second stacked layer 2 is formed on the second surface 3b of the multi-layer board 3, and at least one of the external connection conductors 323 is embedded in the second stacked layer 2. The second stacked layer 2 includes a second organic dielectric layer 21a, a second inorganic dielectric layer 21b, and a second circuit 22 that is embedded in the second organic dielectric layer 21a and the second inorganic dielectric layer 21b. The second organic dielectric layer 21a and the second inorganic dielectric layer 21b are stacked on the second surface 3b.

Specifically, the second organic dielectric layer 21a can be a single-layer structure or a multi-layer structure, and the second inorganic dielectric layer 21b can be a single-layer structure or a multi-layer structure. Furthermore, one end of the second circuit 22 is connected to the multi-layer board 3 (e.g., one of the external connection conductors 323), and another end of the second circuit 22 is exposed from one of the second organic dielectric layer 21a and the second inorganic dielectric layer 21b. It should be noted that the structure of the second circuit 22 in the present embodiment is substantially the same as that described in the first embodiment, and will not be described herein for the sake of brevity.

In the drawings of the present embodiment, the second stacked layer 2 is configured with the second inorganic dielectric layer 21b formed on the second surface 3b and connected to the second modification region 3b1, so that at least one of the external connection conductors 323 is embedded in the second inorganic dielectric layer 21b. Moreover, the second organic dielectric layer 21ais stacked on the second inorganic dielectric layer 21b, so that the another end of the second circuit 22 is exposed from the second organic dielectric layer 21a, but the present disclosure is not limited thereto.

For example, in other embodiments of the present disclosure not shown in the drawings, the second stacked layer 2 can be configured with the second organic dielectric layer 21a formed on the second surface 3b and connected to the second modification region 3b1, so that at least one of the external connection conductors 323 is embedded in the second organic dielectric layer 21a, and the second inorganic dielectric layer 21b is stacked on the second organic dielectric layer 21a for enabling the another end of the second circuit 22 to be exposed from the second inorganic dielectric layer 21b.

The material of the first organic dielectric layer 11a and the material of the second organic dielectric layer 21a can each be selected from at least one of polyimide (PI), ajinomoto build-up film (ABF), liquid crystal polymer (LCP), acrylic, thermoplastics, thermosetting materials, polybenzoxazole (PBO), benzocyclobutene (BCB), epoxy resin, cyanate ester resin, polytetrafluoroethylene, polyester, polyolefin, SU-8, and hybrid polymer-Ceramic Materials.

The material of the first inorganic dielectric layer 11b and the material of the second inorganic dielectric layer 21b can each be selected from at least one of silicon dioxide (SiO₂), aluminum oxynitride (AlON), zirconia-toughened alumina (ZTA), beryllium oxide (BeO), silicon carbide (SiC), aluminum oxide (Al₂O₃), aluminum nitride (AlN), silicon nitride (Si₃N₄), zirconium dioxide (ZrO₂), quartz, mica, hafnium oxide (HfO₂), tantalum pentoxide (Ta₂O₅), magnesium oxide (MgO), titanium dioxide (TiO₂), and boron nitride (BN).

Furthermore, the manufacturing method for the first inorganic dielectric layer 11b and the second inorganic dielectric layer 21b can be chemical vapor deposition (CVD), physical vapor deposition (PVD), or electrophoretic deposition (EPD). It should be noted that Quartz and Mica are minerals extracted from natural ore and then processed or synthesized, and therefore are not formed by deposition.

Specifically, the chemical vapor deposition in the present embodiment can include atomic layer deposition (ALD), high-pressure chemical vapor deposition (HPCVD), plasma-enhanced chemical vapor deposition (PECVD), microwave plasma chemical vapor deposition (MPCVD), low-pressure chemical vapor deposition (LPCVD), vapor phase epitaxy (VPE), metal-organic chemical vapor deposition (MOCVD), or spray pyrolysis.

Furthermore, the physical vapor deposition in the present embodiment can include E-Gun evaporation, ion beam evaporation, DC magnetron sputtering, ion beam sputtering, pulsed laser deposition (PLD), cathodic arc deposition, or molecular beam epitaxy (MBE).

It should be noted that, in other embodiments of the present disclosure not shown in the drawings, the multi-layer board 3 can be applied independently according to practical requirements, and can be used to allow at least one electronic component to be connected thereon.

### [Third Embodiment]

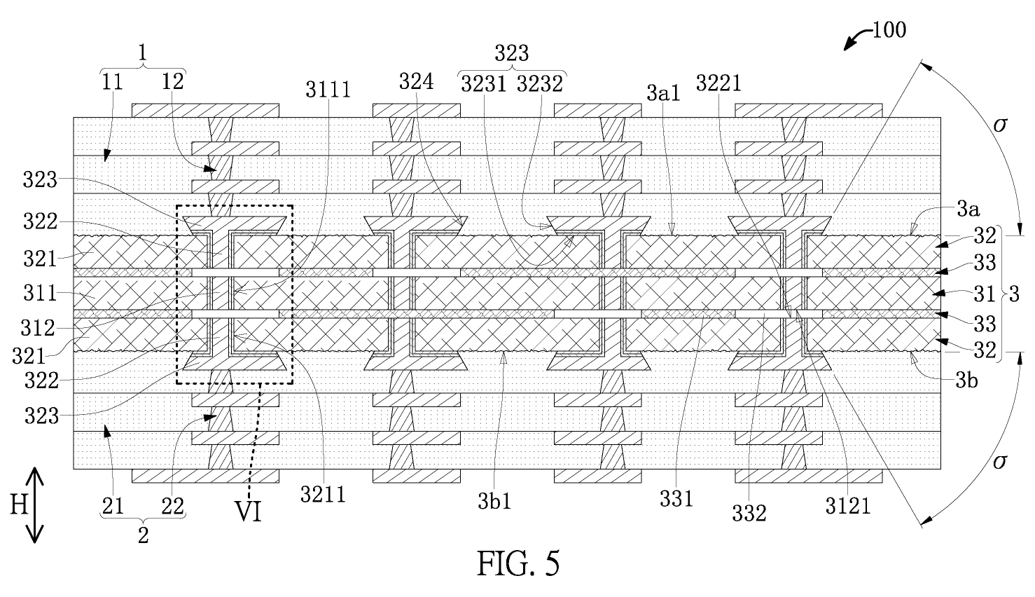

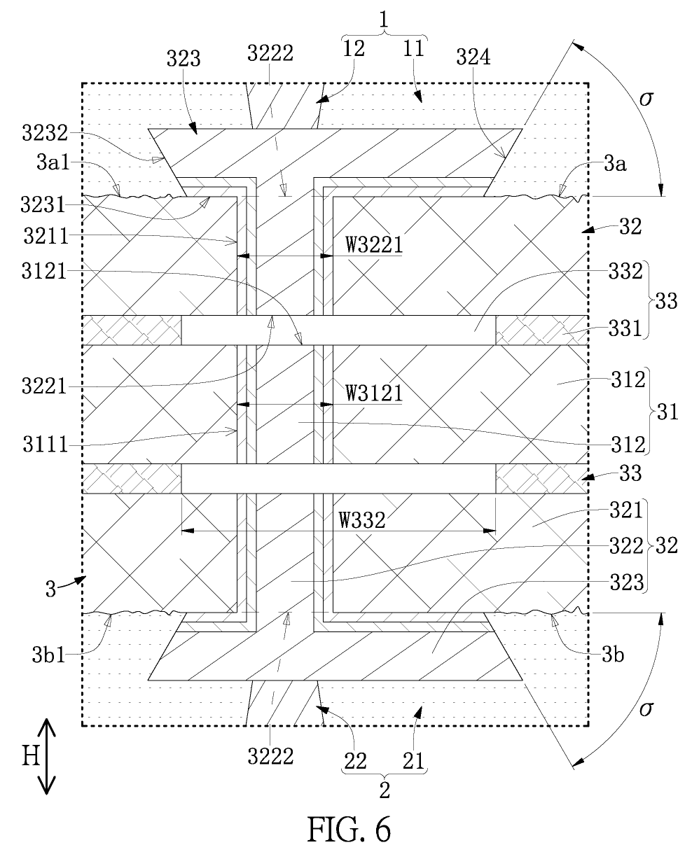

Referring to FIG. 5 to FIG. 7, a third embodiment of the present disclosure, which is similar to the first and second embodiments of the present disclosure, is provided. For the sake of brevity, descriptions of the same components in the first to third embodiments of the present disclosure will be omitted herein, and the following description only discloses different features between the fourth embodiment and the first to second embodiments.

In the present embodiment, the external connection conductor 323 has a bottom surface 3231 connected to the outer surface (e.g., the first surface 3a or the second surface 3b) and a surrounding lateral edge 3232 that is connected to the bottom surface 3231. Moreover, an angle σ formed between the surrounding lateral edge 3232 and the outer surface is an acute angle. The angle σ is within a range from 30 degrees to 75 degrees.

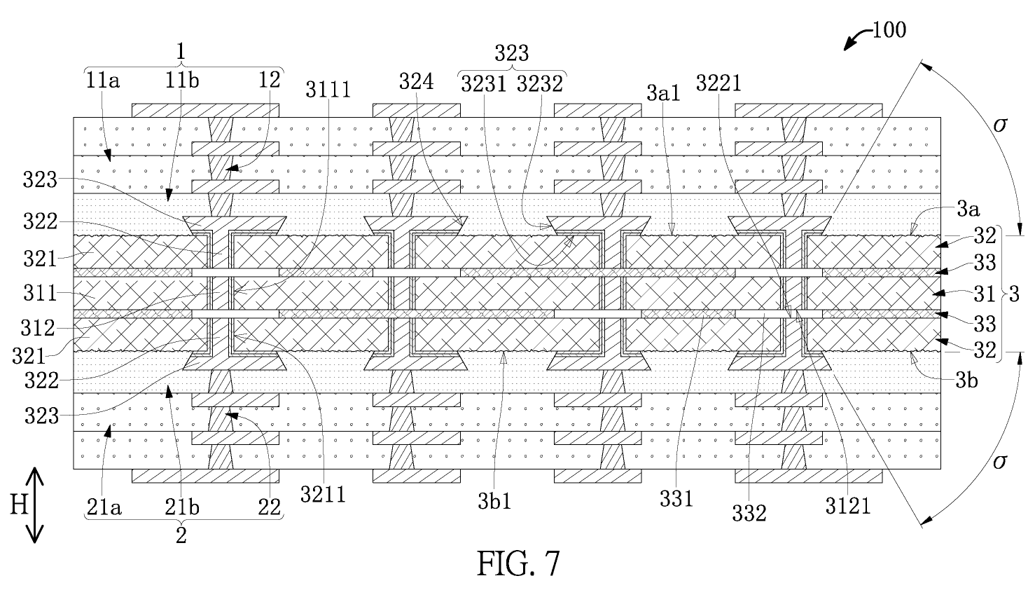

In other words, a ring-shaped groove 324 is formed between the surrounding lateral edge 3232 and the outer surface, and the ring-shaped groove 324 is filled with the first dielectric layer 11 (e.g., as shown in FIG. 5) or is filled with one of the first inorganic dielectric layer 11b and the first organic dielectric layer 11a (e.g., as shown in FIG. 7), so as to further improve the bonding strength between the external connection conductor 323 and the first stacked layer 1 (or the second stacked layer 2) through the formation of the angle σ.

It should be additionally noted that, in other embodiments of the present disclosure not shown in the drawings, the multi-layer board 3 can be applied independently according to practical requirements, and can be used to allow at least one electronic component to be connected thereon.

### [Fourth Embodiment]

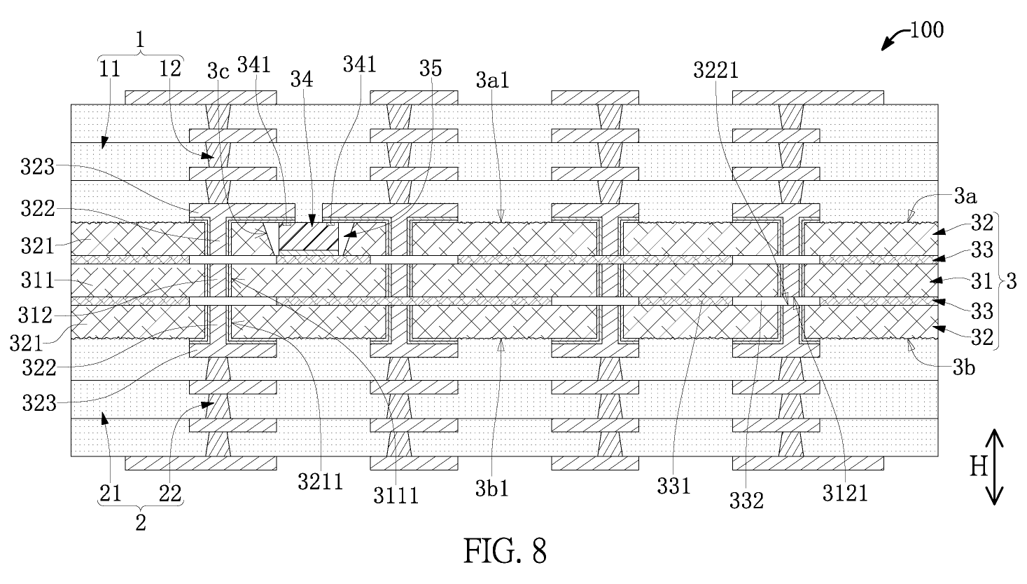

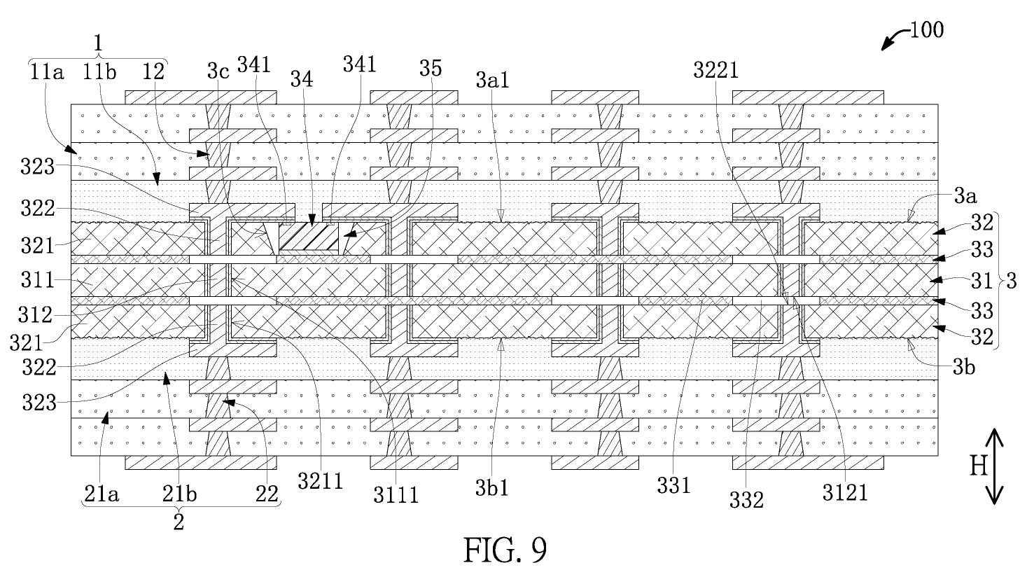

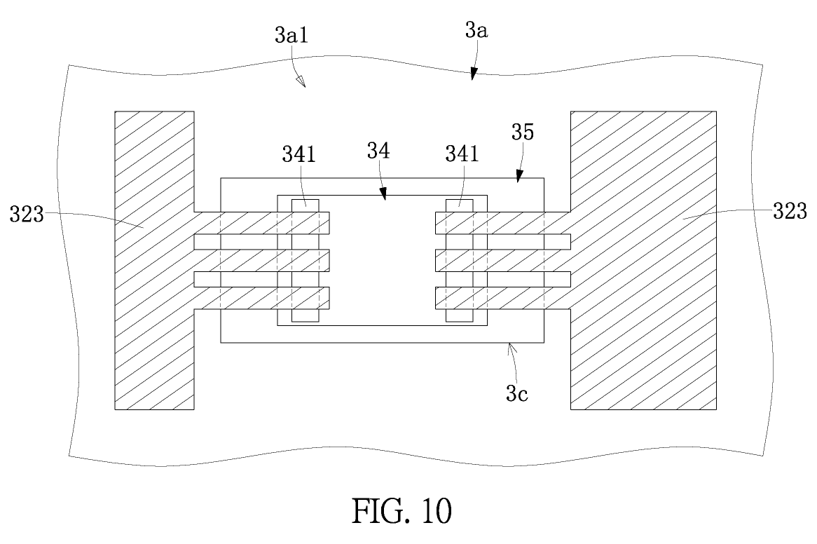

Referring to FIG. 8 to FIG. 11, a fourth embodiment of the present disclosure, which is similar to the first to third embodiments of the present disclosure, is provided. For the sake of brevity, descriptions of the same components in the first to fourth embodiments of the present disclosure will be omitted herein, and the following description only discloses different features between the fourth embodiment and the first to third embodiments.

In the present embodiment, as shown in FIG. 8 to FIG. 10, the multi-layer board 3 further includes an embedded electronic component 34 and an insulator 35. The multi-layer board 3 has an accommodating slot 3c recessed in the first surface 3a, the embedded electronic component 34 is disposed in the accommodating slot 3c with its two electrodes 341 being coplanar with the first surface 3a, and the insulator 35 is filled in the accommodating slot 3c and encapsulates the embedded electronic component 34. Furthermore, the two external connection conductors 323 are respectively connected to the embedded electronic component 34 (e.g., the two electrodes 341) by extending over the insulator 35.

It should be noted that, the embedded electronic component 34 in the present embodiment is located adjacent to the first surface 3a, but the present disclosure is not limited thereto. For example, in other embodiments of the present disclosure not shown in the drawings, the embedded electronic component 34 can be located adjacent to the second surface 3b according to practical requirements.

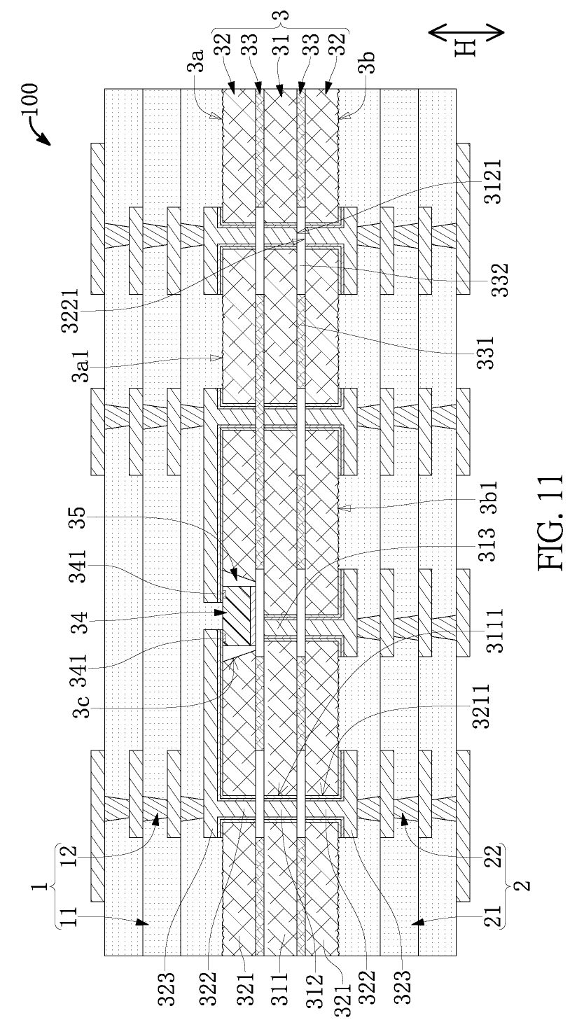

In addition, as shown in FIG. 11, the first core layer 31 includes a conductive pillar 313 embedded in the first substrate 311, and one end of the conductive pillar 313 is arranged adjacent to a bottom of the accommodating slot 3c and is electrically coupled to the embedded electronic component 34.

It should be noted that, in other embodiments of the present disclosure not shown in the drawings, the multi-layer board 3 can be applied independently according to practical requirements, and can be used to allow at least one electronic component to be connected thereon.

### [Beneficial Effects of the Embodiments]

In conclusion, the hybrid circuit board of the present disclosure replaces conventional silicon substrate or conventional glass substrate with a multi-layer board, and ensures that the first stacked layer (e.g., the first circuit) and the second stacked layer (e.g., the second circuit) are electrically coupled to each other through the multi-layer board, thereby effectively improving the heat dissipation and bending resistance of the hybrid circuit board.

Furthermore, in the multi-layer board provided by the present disclosure, the first substrate in the multi-layer board uses a ceramic substrate as the skeleton for the multi-layer board, so that the second substrate can selectively use a ceramic substrate with higher strength, a glass substrate with better high-frequency signal transmission performance, or a copper foil substrate with lower cost, thereby meeting various market requirements.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A multi-layer board, comprising:
a first core layer including:
a first substrate having a first thru-hole, wherein the first substrate is a ceramic substrate; and
a first conductor filled in the first thru-hole, wherein the first conductor has a first internal connection surface that is coplanar with a surface of the first substrate;
a second core layer stacked on the first core layer along a thickness direction and including:
a second substrate having a second thru-hole, wherein the second substrate is one of a ceramic substrate, a glass substrate, and a copper foil substrate; and
a second conductor filled in the second thru-hole, wherein the second conductor has a second internal connection surface that is coplanar with a surface of the second substrate, wherein the first internal connection surface of the first core layer faces the second internal connection surface of the second core layer along the thickness direction; and
a connection layer connected between the first core layer and the second core layer, wherein the connection layer includes:
an insulating layer sandwiched between the first substrate and the second substrate; and
a conductive paste embedded in the insulating layer, wherein the conductive paste connects and is sintered to the first internal connection surface of the first conductor and the second internal connection surface of the second conductor.

2. The multi-layer board according to claim 1, wherein the second core layer includes an external connection conductor connected to the second conductor and away from the second internal connection surface, and wherein the external connection conductor is formed on another surface of the second substrate.

3. The multi-layer board according to claim 2, wherein the second core layer has an accommodating slot recessed in the another surface of the second substrate, and the second core layer includes:
an embedded electronic component disposed in the accommodating slot; and
an insulator filled in the accommodating slot and encapsulating the embedded electronic component, wherein the external connection conductor is connected to the embedded electronic component by extending over the insulator.

4. The multi-layer board according to claim 3, wherein the first core layer includes a conductive pillar embedded in the first substrate, and a first end of the conductive pillar is arranged adjacent to a bottom of the accommodating slot and is electrically coupled to the embedded electronic component.

5. The multi-layer board according to claim 2, wherein the external connection conductor has a bottom surface connected to the another surface of the second substrate and a surrounding lateral edge that is connected to the bottom surface, and an angle formed between the surrounding lateral edge and the another surface of the second substrate is an acute angle.

6. The multi-layer board according to claim 5, wherein the angle is within a range from 30 degrees to 75 degrees.

7. The multi-layer board according to claim 2, wherein the external connection conductor is formed on the another surface of the second substrate in a direct plated copper (DPC) manner.

8. The multi-layer board according to claim 1, wherein the conductive paste includes a solder paste, an active metal brazing (AMB) paste, a nano silver paste, a nano copper paste, or a nanoscale colloidal gold.

9. The multi-layer board according to claim 1, wherein a wall of the first substrate defining the first thru-hole is flush with a wall of the second substrate defining the second thru-hole along the thickness direction.

10. The multi-layer board according to claim 1, wherein a width of the conductive paste is greater than a width of the first internal connection surface and is greater than a width of the second internal connection surface.

11. The multi-layer board according to claim 1, wherein a projection region defined by orthogonally projecting the first internal connection surface onto the second core layer along the thickness direction completely overlaps the second internal connection surface and does not overlap with the second substrate.

12. The multi-layer board according to claim 1, wherein the multi-layer board is configured to allow at least one electronic component to be connected thereon.
